(19) United States
(12) Patent Application Publication
(10) Pub. No.: US 2007/0042185 A1
(43) Pub. Date: Feb. 22, 2007

(54) Diamond diaphragm

(75) Inventors: Jen-Sheuan Huang, Taipei County (TW); Hsiao-Kuo Chang, Taoyuan (TW); Chih-Hsien Chung, Taipei County (TW)

Correspondence Address: BIRCH STEWART KOLASCH & BIRCH, PO BOX 747, FALLS CHURCH, VA, 22040-0747, US

(73) Assignee: KINIK COMPANY

(21) Appl. No.: 11/504,645

(22) Filed: Aug. 16, 2006

(30) Foreign Application Priority Data
Aug. 19, 2005 (TW) 094128522

(51) Int. Cl. B28B 7/38; C23C 16/00; B05D 1/08; B32B 9/00

(52) U.S. Cl. 428/408; 427/248.1; 427/133; 427/446

(57) ABSTRACT

A method for fabricating a diamond diaphragm is provided, wherein a non-homogeneous energy, generated by a hot wire, plasma, or flame, for activating and dissociating gas is provided to pass above a mold. Due to different distances between a curved surface of the mold and the non-homogeneous energy, different heating effects are produced on the surface of the mold. When the diamond material is coated and grows on the surface of the mold, the growth rate of the diamond material appears to be different by location, thus, the diamond diaphragm has a non-homogeneous vibration characteristic, and thereby having a response bandwidth wider than that of a diamond diaphragm with homogeneous vibration characteristic.

### CROSS-REFERENCE TO RELATED APPLICATIONS

This non-provisional application claims priority under 35 U.S.C. §119(a) on Patent Application No(s). 094128522 filed in Taiwan, R.O.C. on Aug. 19, 2005, the entire contents of which are hereby incorporated by reference.

### BACKGROUND OF THE INVENTION

1. Field of Invention

The present invention relates to a diaphragm, and more particularly, to a diamond diaphragm with non-uniform thickness and hardness distribution.

2. Related Art

Hardness and damping characteristic are first taken into consideration when selecting a material for a diaphragm. The hardness determines the natural frequency of the material, i.e., a material with a higher hardness has a corresponding higher natural frequency, and on the contrary, a material with a lower hardness has a corresponding lower natural frequency. A material with a preferred damping characteristic provides the diaphragm with a relatively smooth vibration response, thus, the output value of sound pressure level of the diaphragm is relatively smooth.

Conventionally, common diaphragm materials include: paper, polymeric plastic, metal (Be, Ti, Al), ceramic, etc. Among these diaphragm materials, paper and polymeric plastic have preferred damping characteristics, but they are easily damaged due to the poor stiffness, and the maximum working frequencies are limited by their poor hardness. However, although the metal diaphragm has preferable hardness, metals with high hardness (such as Be, Ti) are expensive and are difficult to be processed. Ceramic material also has a problem of complicated sintering procedures. Since the diamond material has many excellent mechanical characteristics and high strength, it is suitable for fabricating the diaphragm with small weight and high stiffness that is applicable in the medium and high frequency loudspeakers. Since the sound is generated by the vibration of the diaphragm, the higher the vibration frequency of the diaphragm is, the stricter the requirement for the mechanical strength and quality becomes. The above object can be achieved by utilizing the diamond material to fabricate the diaphragm.

Generally speaking, the diaphragm has an upper limit of the response frequency. However, whether the diaphragm is made by diamond or other materials, due to the homogeneous characteristic of the material of the diaphragm, its natural frequency is limited within the specific range, and thereby the bandwidth of the diaphragm is limited. The damping characteristic and the stiffness cannot be changed randomly between each other, so that the sound quality and timbre of the diaphragm are limited. Therefore, in order to cover the frequency range accepted by human ears, multiple diaphragms with different limits of bandwidth and frequency are usually required at the same time to achieve the optimal sound performance. Therefore, in conventional art, there is a technology of utilizing different materials to fabricate the diaphragm section by section, wherein the central part of the diaphragm is made of a high hardness material while the periphery part is made of a low hardness material. The two parts with different hardness and thickness are bonded into a single diaphragm, and the diaphragm with different materials can cover a wider bandwidth. However, due to the extremely small thickness of the diaphragm, bonding one part with another part is difficult. When diamond material being applied for fabricating diaphragm, the bonding procedure and bonding agent are both technical problems, so it is difficult to form a diaphragm with two parts by diamond material.

### SUMMARY OF THE INVENTION

In view of the above problems, the object of the present invention is to provide the method for fabricating a diamond diaphragm, for varying thickness, hardness, and damping characteristics of different areas on the diamond diaphragm, therefore, the diamond diaphragm has non-homogeneous vibration characteristics and thereby covering a relatively wide range of frequencies.

In order to achieve the above object, the present invention provides a method for fabricating a diamond diaphragm, which includes the following steps: first, provide a mold with a curved surface. Second, provide a non-homogeneous energy for activating and dissociating gas. For example, the non-homogeneous energy can be generated by following method:

1. Provide a hot wire, take the hot wire as a central point (the highest energy area), and then the temperature and the concentration of the reactant is distributed in a non-homogeneous annular.

2. Provide plasma activated by high-frequency energy, under the effects of wavelength, amplitude and standing wave of the energy of plasma, the concentration of the reactant is non-homogeneously distributed in a spherical shape.

3. Provide flame, and the energy of the flame attenuates outwardly from the central area, and the concentration of the reactant is non-homogeneously and divergently distributed.

The temperature produced by the above energies and the concentration of the reactant are quickly attenuating from the center to outwards in sequence. Therefore, different locations on the surface of the mold are contacted with areas of different reactant concentrations and temperature, so that diamond grown at different locations on the surface has different crystalline structure and different thickness, thus, the diamond material has non-homogeneous vibration characteristics, for example, the thickness or hardness are non-homogeneously distributed. Then, the diamond film is separated from the mold, thus forming the diamond diaphragm. The crystalline structure of the diamond material can be micro-crystal, nano-crystal, etc.

As for the diamond diaphragm fabricated according to the present invention, due to the non-homogeneous hardness and thickness, the hardness of the central area of the diamond diaphragm is higher than that of the periphery area of the diamond diaphragm, and thickness of the central area of the diaphragm is higher than that of the periphery area of the diaphragm. Therefore, different parts of the diamond diaphragm have different natural frequencies due to the vibration characteristics of the parts being affected by the hardness and thickness, thus, the bandwidth of diamond diaphragm of the present invention is wider than that of a conventional diamond diaphragm.

Further scope of applicability of the present invention will become apparent from the detailed descriptions given hereinafter. However, it should be understood that the detailed descriptions and specific examples, while indicating embodiments of the invention, are given by way of illustration only, since various changes and modifications within the spirit and scope of the invention will become apparent to those skilled in the art from these detailed descriptions.

### BRIEF DESCRIPTION OF THE DRAWINGS

The present invention will become more fully understood from the detailed description given herein below for illustration only, which thus is not limitative of the present invention, and wherein:

FIGS. 1A, 1B, 1C, and 1D are schematic views of fabricating a diamond diaphragm according to a first embodiment of the invention;

FIG. 2A is a top view of a mold according to the first embodiment;

FIG. 2B is a side view of the mold according to the first embodiment;

FIG. 3 is an analysis diagram of the frequency and volume according to the first embodiment and the conventional diaphragm in the art; and

FIGS. 4A, 4B, 4C, and 4D are schematic views of fabricating a diamond diaphragm according to a second embodiment of the present invention.

### DETAILED DESCRIPTION OF THE INVENTION

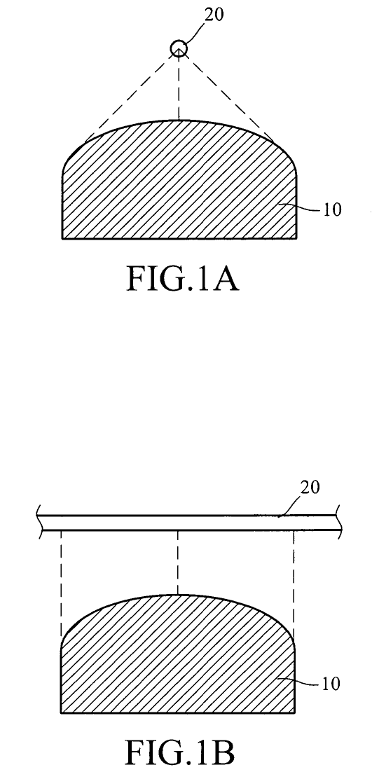

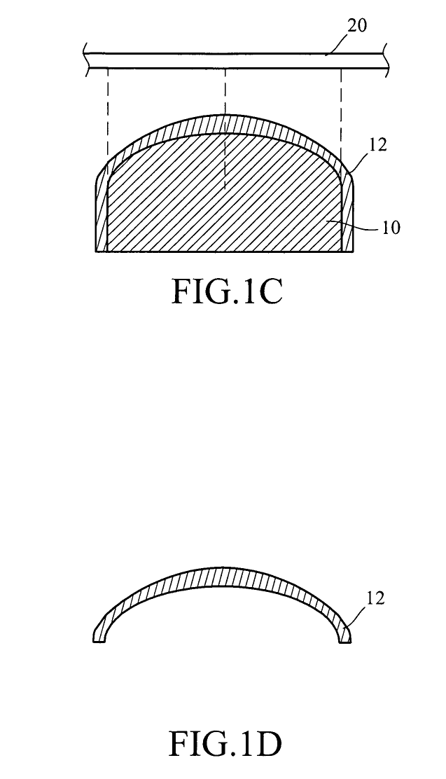

To further understand the object, structure, feature, and function of the present invention, the present invention is further described below in detail with reference to embodiments. Referring to FIGS. 1A, 1B, 1C, and 1D, a diamond diaphragm according to a first embodiment of the present invention is shown. The method for fabricating the diamond diaphragm includes the following steps. First, provide a mold 10, wherein the shape of the mold 10 is configured in order to match with the shape of the diaphragm to be fabricated, and the mold 10 has a curved surface with the central part being protruded. Second, provide a non-homogeneous energy, for activating and dissociating gas, to pass above the mold 10, wherein the non-homogeneous energy is generated by a hot wire, plasma, or flame. A hot wire 20 made of high-temperature resistant tungsten, tantalum, and tungsten carbide is used in this embodiment to generate the non-homogeneous energy, and the temperature of the non-homogeneous energy generated by the hot wire 20 is in the range of 1900° C. to 2300° C. After being charged, the hot wire 20 is heated to a high temperature to heat the mold 10, as shown in FIGS. 1A and 1B. Since the hot wire 20 passes over the mold 10, due to the curved surface configuration of the mold 10, each part of the mold 10 has a different distance from the hot wire 20, thus, the temperature distributed on the surface of the mold 10 is non-uniform.

Then, charge to heat the hot wire 20 to a high-temperature heating for heating the surface of the mold 10, and meanwhile to raise the temperature of the mold 10 up to 400-1000° C. Then, perform a diamond coating procedure, such as chemical vapor deposition, to coat the diamond material on the mold 10, to form a first vibration layer 12 in the shape of a curved film, as shown in FIG. 1C. Separate the first vibration layer 12 from the mold 10, and remove redundant parts, thus the diamond diaphragm of the present invention is accomplished, as shown in FIG. 1D. Since the hot wire 20 provides non-homogeneous energy to the mold 10 and the first vibration layer 12, reactive areas with different temperatures are produced due to different distances, and the concentration of the reactant is distributed in a non-homogeneous annular with the hot wire 20 as the central point (the highest energy area). Due to the different reactive temperatures and reactants with different concentrations for the first vibration layer 12, the diamond material grows on different parts of the mold 10 has different crystallization velocity, so as to form non-homogeneous vibration characteristic distribution. Namely, the central part of the first vibration layer 12 forms a main reactive area, and the nearest to the central part, the faster the diamond material grows, and thereby, the larger the thickness is.

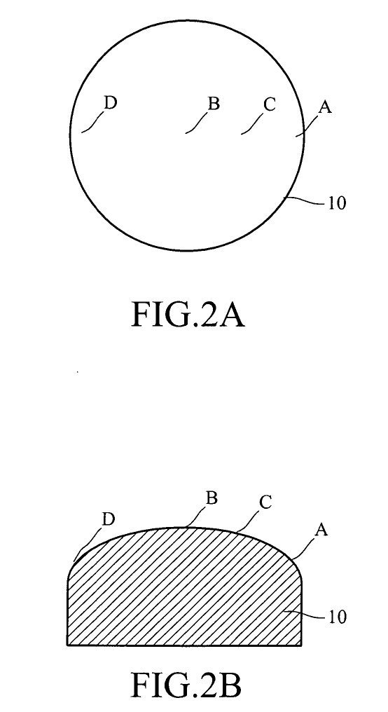

As shown in FIGS. 2A and 2B, among the four points of A, B, C, and D, point B is nearest to the high-temperature reactive area, A and D are farthest from the high-temperature reactive area, so the first vibration layer 12 grows to the largest thickness at point B, and the first vibration layer 12 grows to the smallest thickness at points A and D. The relationship of the thickness variation is B>C>A=D, and their thicknesses are falling within the range of about 3 to 50 μm. Since the first vibration layer 12 has different thicknesses at each point (the four points of A, B, C, and D), they have different vibration characteristics, so as to have different highest natural frequencies, thus, the diamond diaphragm composed by the first vibration layer 12 has a wider bandwidth compared with the diaphragm with a single thickness.

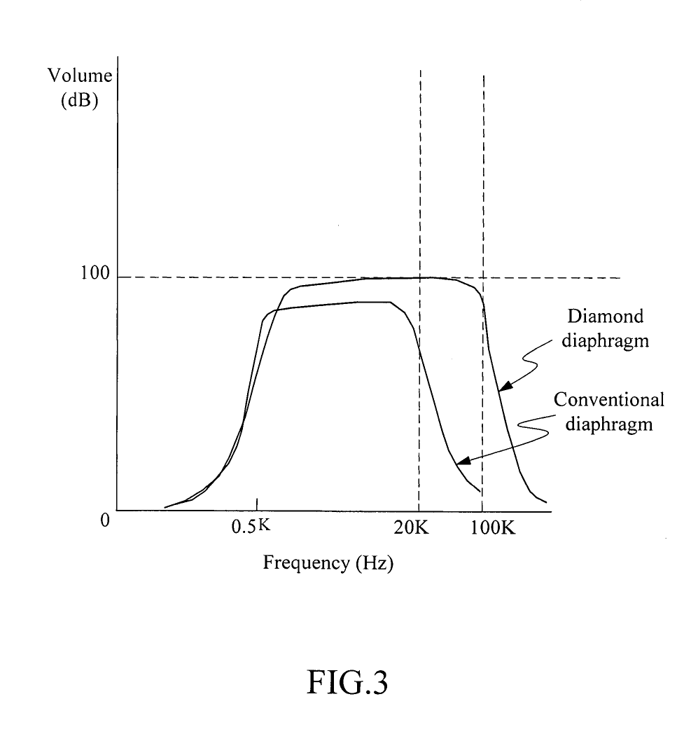

As shown in FIG. 3, after a conventional diaphragm with a single hardness or thickness reaches a certain high frequency (about 20 KHz), the volume (dB) of the decays quickly, but the present invention can further promote the upper limit of the frequency and maintains to begin decaying until 100 KHz. Furthermore, the diamond material has the characteristics of being hard, crisp, and with high damping coefficient, which makes the sound pressure level output by the first vibration layer 12 is smoother.

As described above, the non-homogeneous energy can be generated by the hot wire 20, plasma, or flame. Due to the different energy generating methods, the distributions of the reactive temperature and the reactant concentration are different, and all the method for generating non-homogeneous energy is provided for making the diamond material grow with non-homogeneous crystallization velocity, so that the formed diamond diaphragm has non-homogeneous vibration characteristic. When the plasma is provided for generating the non-homogenous energy, the wavelength and the standing wave of the high-frequency energy activated plasma form a relationship with the surface of the mold, thus, the amplitude of the plasma at each point of the surface of the mold is different, therefore, the reactant concentration on the surface of the mold is non-homogeneously distributed in a spherical shape. When the flame is provided for generating the non-homogeneous energy, the energy provided by the flame attenuates outwardly with the flame as the central point, and the reactant concentration is non-homogeneous divergently distributed, thus, the diamond materials on the surface of the mold have different crystallization velocities due to different distances from the flame, so as to form the diamond diaphragm with the non-homogeneous vibration characteristic.

Moreover, the different reactive temperature also makes the diamond material grow to different crystalline structures. In the high-temperature reaction and growth area, for example, the position of Point B in FIGS. 2A and 2B, in the microstructure of the diamond material formed thereby, the proportion of the SP3 bonding diamond is high, thus, the structure formed by the diamond material at the position of Point B has a higher hardness. As for the points A, C, and D far away from the high-temperature reaction and growth area, the proportion of SP2 bonding diamond in the microstructure of the diamond material increases as the temperature drops, thus, the diamond material at point A, B, and C has a lower hardness. That is, as for the overall physical characteristic of the first vibration layer 12, the hardness of the material near the protruding part at the center is high, and the hardness of the material far from the protruding part has been gradually declined. The material of different part has different hardness, thus, each local part has a different natural response frequency within the range from low to high frequencies, so as to widen the bandwidth of the first vibration layer 12.

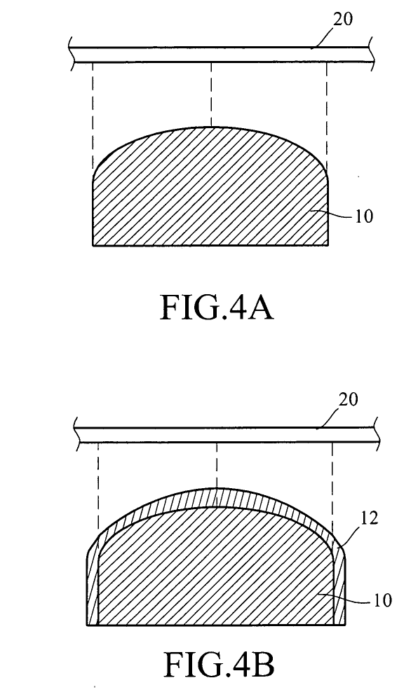

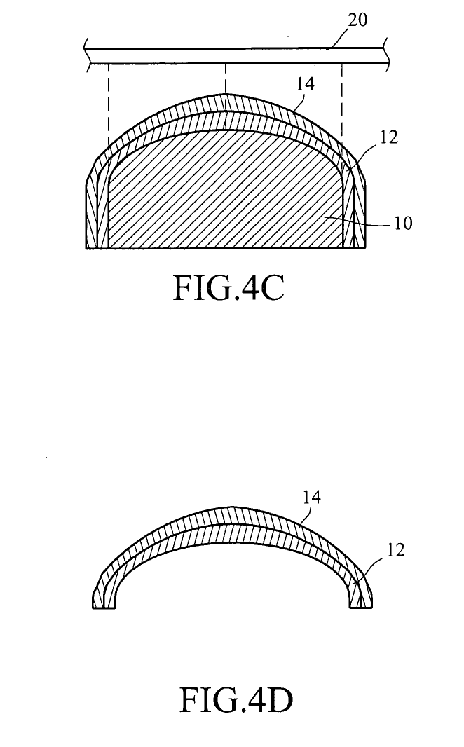

Referring to FIGS. 4A, 4B, 4C, and 4D, a diamond diaphragm according to a second embodiment of the present invention is shown. The present invention is not limited to the composition of a single-layer structure, but may form a multi-layer structure under different growth conditions. Different growth condition of the structure of each layer results in different thickness and hardness, thus, the vibration characteristic of the diamond diaphragm is adjusted by multi-layer structures.

The second embodiment is illustrated through a two-layered structure, and practically, a structure of more than two layers may be formed in this embodiment. First, provide a mold 10, wherein the shape of the mold 10 is configured to form a curved surface with the central part being protruded, so as to match the configuration required by the diamond diaphragm. Then, provide a non-homogeneous energy, generated by a hot wire 20, plasma, or flame, for activating and dissociating the gas, to pass above the mold 10. A hot wire 20 is used in this embodiment to generate the non-homogeneous energy, and after the hot wire 20 has been charged, and the temperature of the non-homogeneous energy generated by the hot wire 20 is in the range of 1900° C. to 2300° C., and meanwhile, the temperature of the mold 10 is raised to 400° C.-1000° C. Then, coat the diamond material on the surface of the mold 10 by diamond coating procedure with the non-homogeneous energy for activating and dissociating gas, such as chemical vapor deposition, to form a first vibration layer 12 on the surface of the mold 10, and then, by utilizing the difference of the temperature condition, the first vibration layer 12 is formed into a configuration that is thick in center while thin in periphery, and hard in center while soft in periphery. Then, through changing the coating condition, including the heating temperature of the hot wire 20, the distance of the hot wire 20, the temperature of the mold 10, the pressure, the gas concentration, the flow, etc., a second vibration layer 14 is further formed above the first vibration layer 12, which is also formed into a configuration that is thick in center while thin in periphery and hard in center while soft in periphery. In addition, since the coating condition of the second vibration layer 14 is different from that of the first vibration layer 12, the vibration characteristic of the second vibration layer 14 is also different from that of the first vibration layer 12. The vibration characteristic of the diamond diaphragm may be adjusted by utilizing the first vibration layer 12 and the second vibration layer 14 to form a composite structure, so as to achieve an optimal vibration characteristic. The first vibration layer 12 and the second vibration layer 14 that are integrated as a whole are separated form the mold 10, thus, the diamond diaphragm of this embodiment is accomplished. Of course, a third and a forth vibration layers can be continuously coated on the second vibration layer 14, thus, the vibration characteristic of the diamond diaphragm is optimized by using more vibration layers.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for fabricating a diamond diaphragm, comprising the following steps:
providing a mold with a curved surface;
providing a non-homogeneous energy for activating and dissociating gas to pass above the mold, to generate a high temperature for heating the mold, thereby the temperature distributed on the surface of the mold is non-uniform; and
coating a diamond material on the surface of the mold to form a vibration layer with a non-homogeneous hardness.

2. The method for fabricating a diamond diaphragm as claimed in claim 1, wherein the non-homogeneous energy is generated by a hot wire made of tungsten, tantalum, or tungsten carbide.

3. The method for fabricating a diamond diaphragm as claimed in claim 1, wherein the temperature of non-homogeneous energy is 1900° C.-2300° C.

4. The method for fabricating a diamond diaphragm as claimed in claim 1, wherein the non-homogeneous energy is generated by plasma or flame.

5. The method for fabricating a diamond diaphragm as claimed in claim 1, wherein the temperature of the mold is heated to 400° C.-1000° C.

6. The method for fabricating a diamond diaphragm as claimed in claim 1, further comprising a plurality of diamond coating steps for stacking a plurality of vibration layers on the mold.

7. The method for fabricating a diamond diaphragm as claimed in claim 6, wherein each of the diamond coating steps are provided with a different coating condition, so that each of the vibration layers has a different vibration characteristic.

8. A method for fabricating a diamond diaphragm, comprising the following steps:
providing a mold with a curved surface;
providing a non-homogeneous energy for activating and dissociating gas to pass above the mold, to generate a high temperature for heating the mold, thereby the temperature distributed on the surface of the mold is non-uniform; and
coating a diamond material on the surface of the mold to form a vibration layer with a non-homogeneous thickness.

9. The method for fabricating a diamond diaphragm as claimed in claim 8, wherein the non-homogeneous energy is generated by a hot wire made of tungsten, tantalum, or tungsten carbide.

10. The method for fabricating a diamond diaphragm as claimed in claim 8, wherein the temperature of the non-homogeneous energy is 1900° C.-2300° C.

11. The method for fabricating a diamond diaphragm as claimed in claim 8, wherein the non-homogeneous energy is generated plasma or flame.

12. The method for fabricating a diamond diaphragm as claimed in claim 8, wherein the temperature of the mold is heated to 400° C.-1000° C.

13. The method for fabricating a diamond diaphragm as claimed in claim 8, further comprising a plurality of diamond coating steps for stacking a plurality of vibration layers on the mold.

14. The method for fabricating a diamond diaphragm as claimed in claim 13, wherein each of the diamond coating steps are provided with a different coating condition, so that each of the vibration layers has a different vibration characteristic.

15. A diamond diaphragm, comprising a vibration layer formed by diamond material with a curved surface, the improvement characterized by that the thickness of the diamond diaphragm is non-homogeneously distributed, and the thickness of the central area of the vibration layer is larger than that of the periphery area of the vibration layer.

16. The diamond diaphragm as claimed in claim 15, wherein the diamond diaphragm comprises a plurality of vibration layers and the thickness of each of the vibration layers is non-homogeneously distributed.

17. The diamond diaphragm as claimed in claim 16, wherein the thickness of each of the vibration layers is in the range of 3 μm to 50 μm.

18. A diamond diaphragm, comprising a vibration layer formed by with a curved surface, the improvement characterized by that the hardness of the diamond diaphragm is non-homogeneously distributed, and the hardness of the central area of the vibration layer is higher than that of the periphery area of vibration layer.

19. The diamond diaphragm as claimed in claim 16, wherein the diamond diaphragm comprises a plurality of vibration layers, and the hardness of each of the vibration layers is non-homogeneously distributed.

20. The diamond diaphragm as claimed in claim 17, wherein the diamond material comprises SP3 bonding diamond and SP2 bonding diamond, wherein the hardness of the diamond material is changed by varying the proportion of the SP3 bonding diamond and SP2 bonding diamond.
